(19) United States
(12) Patent Application Publication
(10) Pub. No.: US 2021/0367188 A1
(43) Pub. Date: Nov. 25, 2021

(54) THIN FILM ENCAPSULATION LAYER, ORGANIC LIGHT-EMITTING DIODE DEVICE, AND FABRICATING METHOD THEREOF

(71) Applicant: Wuhan China Star Optoelectronics Semiconductor Display Technology Co., LTD., Wuhan, Hubei (CN)

(72) Inventor: Jiajia SUN, Wuhan (CN)

(21) Appl. No.: 16/623,059

(22) PCT Filed: Nov. 15, 2019
(86) PCT No.: PCT/CN2019/119002

§ 371 Date: Dec. 16, 2019

(30) Foreign Application Priority Data
Sep. 3, 2019 (CN) 201910825784.4

(51) Int. Cl. H01L 51/52

(52) U.S. Cl. CPC H01L 51/5237; H01L 51/502

(57) ABSTRACT

A thin film encapsulation layer, an organic light-emitting diode (OLED) device, and a fabricating method thereof are provided. The thin film encapsulation layer includes a first inorganic layer, an organic layer, and a second inorganic layer, which are stacked. The organic layer contains a one-dimensional tubular nanomaterial. The OLED device includes an array substrate, a light-emitting layer, and the thin film encapsulation layer, which are stacked. The thin film encapsulation layer is disposed on the array substrate and completely covers the light-emitting layer. The method of fabricating the thin film encapsulation layer includes forming the first inorganic layer, forming the organic layer, and forming the second inorganic layer.

### FIELD OF INVENTION

The present invention relates to the field of displays, and in particular, to a thin film encapsulation layer, an OLED device, and a method of fabricating the same.

### BACKGROUND OF INVENTION

Organic light-emitting diodes (OLEDs) have advantages of being light weight, wide viewing angles, fast response times, low temperature resistance, and high luminous efficiency compared with conventional liquid crystal displays. Therefore, OLEDs have been regarded as next generation of new display technology in display industry. In particular, OLEDs can be made into a flexible device which can be folded on a flexible substrate, which is a unique advantage of OLEDs.

In order to realize flexible encapsulation of OLED devices, in recent years, thin film encapsulation has gradually become mainstream of OLED devices encapsulation technology, and the thin film encapsulation generally adopts a sandwich film layer structure having a first inorganic layer, an organic layer, and a second inorganic layer in a stack. The first inorganic layer and the second inorganic layer serve as a water-oxygen barrier layer, and the organic layer serves as a buffer layer for relieving internal stress of the inorganic layer and enhancing flexibility of the OLED devices. Such a sealed encapsulation greatly protects the OLED devices, thereby effectively preventing external water and oxygen from damaging the OLED devices.

However, highly airtight thin film encapsulation can cause difficulties in thermal dissipation of the OLED devices, which seriously restricts efficiency and service life of the OLED devices. Therefore, how to ensure that the OLED devices have both highly airtight property and high thermal dissipation property is an urgent technical problem to be solved.

### Technical Problem

The objective of the present invention is to provide a thin film encapsulation layer, an OLED device, and a fabricating method thereof, which ensure that the OLED devices have highly airtight property and high thermal dissipation property, thereby facilitating thermal dissipation of the OLED devices and improving efficiency and service life of the OLED devices.

### SUMMARY OF INVENTION

### Technical Solution

In order to solve the above problems, the present invention provides a thin film encapsulation layer including a first inorganic layer, an organic layer, and a second inorganic layer disposed in a stacked manner. More specifically, the organic layer is disposed on the first inorganic layer, the second inorganic layer is disposed on the organic layer, wherein the organic layer includes a one-dimensional tubular nanomaterial.

Further, the organic layer and the second inorganic layer are disposed in a stack at least once.

Further, the one-dimensional tubular nanomaterial includes boron nitride nanotubes.

Further, the one-dimensional tubular nanomaterial has a weight percentage of less than 5 wt %.

Further, the one-dimensional tubular nanomaterial has an axial thermal conductivity greater than 100 W/mK.

The invention also provides a method of fabricating the above thin film encapsulation layer, including the steps of:

forming a first inorganic layer;

forming an organic layer on the first inorganic layer, wherein the organic layer includes a one-dimensional tubular nanomaterial; and

forming a second inorganic layer on the organic layer.

Further, the method of fabricating the thin film encapsulation layer further including performing the steps of forming at least one organic layer and at least one inorganic layer in a stack at least once, which includes forming the organic layer on the second inorganic layer, and again forming the second inorganic layer on the organic layer.

Further, the one-dimensional tubular nanomaterial has a weight percentage of less than 5 wt %.

Further, forming the organic layer includes one of inkjet printing, spin coating, or screen printing, and curing the organic layer includes ultraviolet ray curing or heat curing.

The present invention also provides an organic light-emitting diode (OLED) device including an array substrate, a light-emitting layer, and a thin film encapsulation layer, which are stacked. Specifically, the light-emitting layer is disposed on the array substrate; and the thin film encapsulation layer is disposed on the array substrate and completely covers the light-emitting layer.

The invention also provides a method of fabricating the OLED device, including the steps of:

a step of providing the array substrate;

a step of forming the light-emitting layer, wherein the light-emitting layer is formed on the array substrate; and

a step of forming the thin film encapsulation layer, wherein the thin film encapsulation layer is formed on the array substrate and the thin film encapsulation layer completely covers the light-emitting layer.

Meanwhile, the step of forming the thin film encapsulation layer is same as aforementioned, and is not repeated here.

### Beneficial Effect

The invention has beneficial effects of providing a thin film encapsulation layer, an OLED device, and a fabricating method thereof, which utilizes a one-dimensional tubular nanomaterial in an organic layer of the thin film encapsulation layer and ensures the OLED device has both highly airtight property and high thermal dissipation property, thereby facilitating thermal dissipation of the OLED device and improving efficiency and service life of the OLED device.

### BRIEF DESCRIPTION OF FIGURES

FIG. 1 is a schematic view showing a structure of a thin film encapsulation layer according to a first embodiment of the present invention.

FIG. 2 is a schematic view showing another structure of the thin film encapsulation layer according to the first embodiment of the present invention.

FIG. 3 is a schematic view showing a structure of a one-dimensional tubular nanomaterial distributed on an organic layer according to the first embodiment of the present invention.

FIG. 4 is a flowchart showing a method of fabricating the thin film encapsulation layer according to the first embodiment of the present invention.

FIG. 5 is a schematic structural view of an organic light-emitting diode (OLED) device according to the first embodiment of the present invention.

FIG. 6 is a flowchart showing a method of fabricating the OLED device according to the first embodiment of the present invention.

FIG. 7 is a schematic structural view showing boron nitride nanotubes according to a second embodiment of the present invention.

Some of illustrated component numbers are as follows:

100 OLED device;

10 thin film encapsulation layer; 11 first inorganic layer; 12 organic layer; 13 second inorganic layer;

20 light-emitting layer; 30 array substrate; and 121 one-dimensional tubular nanomaterial.

### DETAILED DESCRIPTION OF EMBODIMENTS

In the present invention, the first feature “on” or “under” the second feature can include direct contact of the first and second features, and can also be included that the first and second features are not in direct contact but are contacted by additional features between them, unless otherwise specifically defined and defined. Moreover, the first feature is “above”, “on”, and “on the top of” of the second feature, including the first feature directly above and diagonally above the second feature, or simply means that the first feature is horizontally higher than the second feature. The first feature is “under”, “below”, and “beneath” the second feature, including the first feature directly below and diagonally below the second feature, or merely the first feature is horizontally less than the second feature.

In the present invention, in the drawings, like reference numerals designate corresponding parts throughout the several views, when the terms “first”, “second”, and the like can be used to describe various components, these components are not necessarily limited to the above wording. The above wording is only used to distinguish one component from another.

### First Embodiment

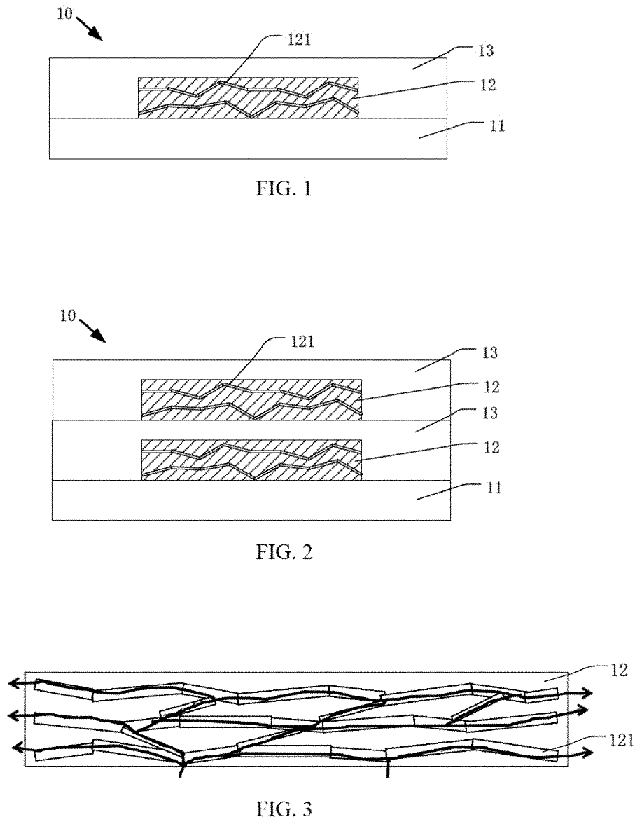

Referring to FIG. 1, a first embodiment of the present invention provides a thin film encapsulation layer 10, including a first inorganic layer 11, an organic layer 12, and a second inorganic layer 13 disposed in a stacked manner. More specifically, the organic layer 12 is disposed on the first inorganic layer 11 and the second inorganic layer 13 is disposed on the organic layer 12, wherein the organic layer 12 includes a one-dimensional tubular nanomaterial 121.

Referring to FIG. 2, in this embodiment, the organic layer 12 and the second inorganic layer 13 are formed in an alternate stack at least once, preferably two times, three times, or four times; such alternating stack arrangement is good for isolating water and oxygen and maintaining good thermal dissipation and bending performance.

In this embodiment, the one-dimensional tubular nanomaterial 121 has a weight percentage of less than 5 wt %. This ensures light transmittance of the organic layer 12 in the thin film encapsulation layer 10.

Please refer to FIG. 3, which is a schematic view showing a structure of the one-dimensional tubular nanomaterial 121 distributed in the organic layer 12, wherein the one-dimensional tubular nanomaterial 121 can form a good orientation in the organic layer 12 by inkjet printing, spin coating, screen printing, etc., and the oriented one-dimensional tubular nanomaterial 121 can make the organic layer 12 have anisotropic thermal conductivity, that is, its inside surface thermal conductivity is much greater than its outside surface thermal conductivity. Lines with arrow and arrow direction of each line shown in FIG. 3 indicate directions of heat conduction, the ingredients of the one-dimensional tubular nanomaterial 121 are connected to each other to timely conduct heat of the organic layer 12 from the thin film encapsulation layer 10, thereby improving thermal dissipation performance of the thin film encapsulation layer 10, which ensures luminous efficiency and service life of the thin film encapsulation layer 10.

The one-dimensional tubular nanomaterial 121 has an axial thermal conductivity greater than 100 W/mK, preferably 150 W/mK, 200 W/mK, 250 W/mK, 300 W/mK, 350 W/m K, 400 W/mK, 450 W/mK, and 500 W/mK. The one-dimensional tubular nanomaterial 121 acts as a highly thermal conductive filler, which timely conducts heat of the organic layer 12 from the thin film encapsulation layer 10, thereby improving thermal dissipation performance of the thin film encapsulation layer 10, and ensures luminous efficiency and service life of the thin film encapsulation layer 10.

In this embodiment, a material of the organic layer 12 is selected from one or a combination of epoxy resin, silicon-based polymer, and polymethyl methacrylate. A forming method of the organic layer 12 includes coating which is selected from one of inkjet printing, spin coating, or screen printing, and curing the organic layer 12 by ultraviolet ray or heat. The organic layer 12 has a thickness of about 8 μm to 12 μm.

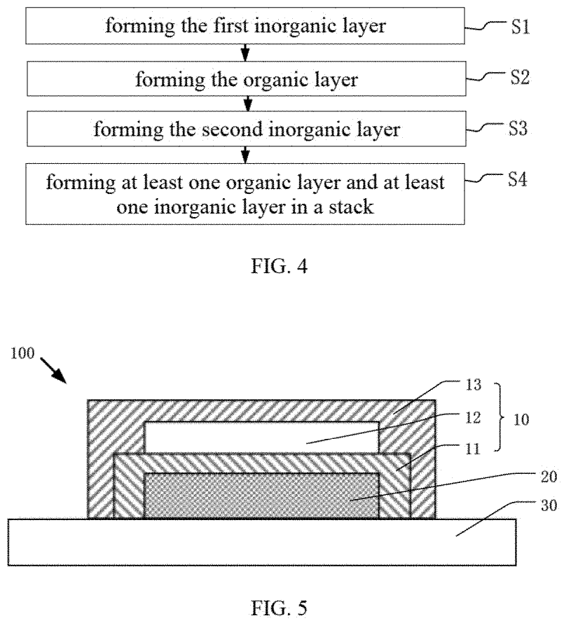

Referring to FIG. 4, in the first embodiment, a method of fabricating the above-mentioned thin film encapsulation layer 10 is further provided, which includes the following steps S1-S3:

S1, a step of forming the first inorganic layer 11, wherein the first inorganic layer 11 is formed;

S2, a step of forming the organic layer 12, wherein the organic layer 12 is formed on the first inorganic layer 11, and the organic layer 12 includes the one-dimensional tubular nanomaterial 121; and

S3, a step of forming the second inorganic layer 12, wherein the second inorganic layer 13 is formed on the organic layer 12.

Referring to FIG. 4, the method of fabricating the thin film encapsulation layer 10 further includes performing the steps of:

S4, a step of forming at least one organic layer 12 and at least one inorganic layer 13 in a stack, which disposes another organic layer 12 on the previously disposed second inorganic layer 13 and subsequently disposes another second inorganic layer 13 on the previously disposed organic layer 12; this step is performed at least once. The organic layer 12 and the second inorganic layer 13 can be alternately stacked a plurality of times, preferably two times, three times, or four times. Such alternating stack arrangement of the organic layer 12 and the second inorganic layer 13 is good for isolating water and oxygen and maintaining good thermal dissipation and bending performance.

In this embodiment, the one-dimensional tubular nanomaterial 121 has a weight percentage of less than 5 wt %. This ensures light transmittance of the organic layer 12 in the thin film encapsulation layer 10.

In this embodiment, the forming method of the organic layer 12 includes coating which is selected from one of inkjet printing, spin coating, or screen printing; such coating manner enables the one-dimensional tubular nanomaterial 121 having good orientation in the organic layer 12; and curing the organic layer 12 by ultraviolet ray or heat. The material of the organic layer 12 is selected from one or a combination of epoxy resin, silicon-based polymer, and polymethyl methacrylate. The organic layer 12 has a thickness of about 8 μm to 12 μm.

In this embodiment, the method of fabricating the first inorganic layer 11 and the second inorganic layer 13 includes one or more combinations of atomic layer deposition (ALD) process, pulsed laser deposition (PLD) process, sputtering process, and plasma enhanced chemical vapor deposition (PECVD) process. Materials of the first inorganic layer 11 and the second inorganic layer 13 include one or more combinations of silicon nitride, silicon oxide, silicon carbide, silicon carbonitride, aluminum oxide, and the like. A thickness of the first inorganic layer 11 and the second inorganic layer 13 ranges from 0.1 μm to 1.5 μm.

Referring to FIG. 5, an organic light-emitting diode (OLED) device 100 is further provided in the first embodiment, including an array substrate 30, a light-emitting layer 20, and the thin film encapsulation layer 10, which are stacked in this order from bottom to top. The light-emitting layer 20 is disposed on the array substrate 30. The thin film encapsulation layer 10 is disposed on the array substrate 30 and completely covers the light-emitting layer 20. More specifically, the first inorganic layer 11 of the thin film encapsulation layer 10 is disposed on the array substrate 30 and completely covers the light-emitting layer 20. The light-emitting layer 20 includes an organic light-emitting diode.

The one-dimensional tubular nanomaterial 121 in the thin film encapsulation layer 10 is filled in the organic layer 12 of the OLED device 100 as a highly thermal conductive filler, and the heat generated by the light-emitting layer 20 can be timely conducted from the thin film encapsulation layer 10, thereby improving thermal dissipation performance of the OLED device 100, and ensuring luminous efficiency and service life of the OLED device 100.

Referring to FIG. 6, a method of fabricating the OLED device 100 is further provided in the first embodiment, including the following steps:

S10, a step of providing the array substrate 30;

S20, a step of forming the light-emitting layer 20, wherein the light-emitting layer 20 is formed on the array substrate 30; and S30, a step of forming the thin film encapsulation layer 10, wherein the thin film encapsulation layer 10 is formed on the array substrate 30 and the thin film encapsulation layer 10 completely covers the light-emitting layer 20.

Meanwhile, the step of forming the thin film encapsulation layer 10 is same as the step shown in FIG. 4, and is not repeated here. This embodiment does not require additional new process steps and is therefore extremely feasible.

### Second Embodiment

In the second embodiment, all technical features in the first embodiment are included, and the distinguishing feature is that, in the second embodiment, the one-dimensional tubular nanomaterial 121 includes boron nitride nanotubes. The boron nitride nanotubes have an axial thermal conductivity of 180-300 W/mK, and thermal conductivity is superior to most of the metal materials. Compared with carbon nanotubes, the boron nitride nanotubes are more stable in chemical and mechanical properties and are more reliable.

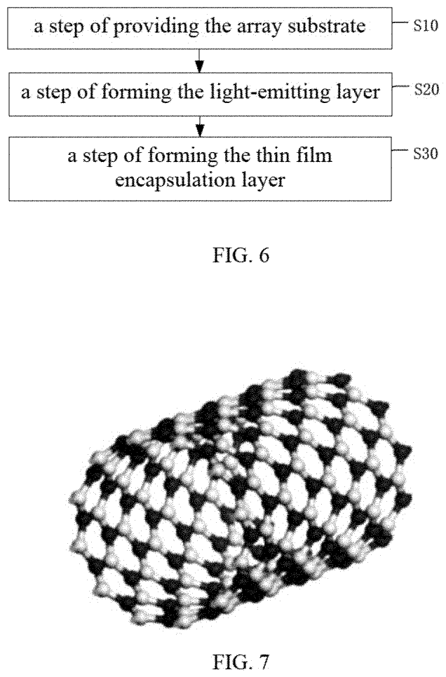

Please refer to FIG. 7, where FIG. 7 is a schematic structural view showing the boron nitride nanotubes, the structure of which is similar to that of the carbon nanotubes. The boron nitride nanotubes are of a hollow structure, compared with other one-dimensional solid thermal conductive filler, and the hollow structure makes it lighter in same volume and more in line with requirements of being light weight.

In order to ensure light transmittance of the organic layer 12 in the thin film encapsulation layer 10, the present embodiment preferably uses single or multi-walled boron nitride nanotubes, and the boron nitride nanotubes are preferably five layers, six layers, seven layers, eight layers, nine layers, or ten layers. More preferably, it is five layers, which is more advantageous for light transmittance of the organic layer 12.

The boron nitride nanotubes can form a good orientation in the organic layer 12 by one of inkjet printing, spin coating, or screen printing, etc., and the oriented boron nitride nanotubes can make the organic layer 12 have anisotropic thermal conductivity, that is, its inside surface thermal conductivity is much greater than its outside surface thermal conductivity. The ingredients of the boron nitride nanotubes are connected to each other to timely conduct heat of the organic layer 12 from the thin film encapsulation layer 10, thereby improving thermal dissipation performance of the thin film encapsulation layer 10, which ensures luminous efficiency and service life of the thin film encapsulation layer 10.

The present invention has advantages of providing a thin film encapsulation layer, an OLED device, and a fabricating method thereof, in which the OLED device has highly airtight property and highly thermal dissipation by adopting a one-dimensional tubular nanomaterial in an organic layer of the thin film encapsulation layer. Thereby, thermal dissipation of the OLED device is facilitated, and efficiency and service life of the OLED device are improved.

Embodiments of the present invention have been described, but not intended to impose any unduly constraint to the appended claims. For a person skilled in the art, any modification of equivalent structure or equivalent process made according to the disclosure and drawings of the present invention, or any application thereof, directly or indirectly, to other related fields of technique, is considered encompassed in the scope of protection defined by the claims of the present invention.

What is claimed is:

1. A thin film encapsulation layer, comprising:
a first inorganic layer;
an organic layer disposed on the first inorganic layer; and
a second inorganic layer disposed on the organic layer;
wherein the organic layer comprises a one-dimensional tubular nanomaterial.

2. The thin film encapsulation layer according to claim 1, wherein the organic layer and the second inorganic layer are disposed in a stack at least once.

3. The thin film encapsulation layer according to claim 1, wherein the one-dimensional tubular nanomaterial comprises boron nitride nanotubes.

4. The thin film encapsulation layer according to claim 1, wherein the one-dimensional tubular nanomaterial has a weight percentage of less than 5 wt %.

5. The thin film encapsulation layer according to claim 1, wherein the one-dimensional tubular nanomaterial has an axial thermal conductivity greater than 100 W/mK.

6. A method of fabricating a thin film encapsulation layer, comprising the steps of:
forming a first inorganic layer;
forming an organic layer on the first inorganic layer, wherein the organic layer comprises a one-dimensional tubular nanomaterial; and
forming a second inorganic layer on the organic layer.

7. The method of fabricating the thin film encapsulation layer according to claim 6, further comprising performing the steps of forming at least one organic layer and at least one inorganic layer in a stack at least once, which comprises forming the organic layer on the second inorganic layer, and again forming the second inorganic layer on the organic layer.

8. The method of fabricating the thin film encapsulation layer according to claim 6, wherein the one-dimensional tubular nanomaterial has a weight percentage of less than 5 wt %.

9. The method of fabricating the thin film encapsulation layer according to claim 6, wherein forming the organic layer comprises one of inkjet printing, spin coating, or screen printing, and curing the organic layer comprises ultraviolet ray curing or heat curing.

10. An organic light-emitting diode device, comprising:
an array substrate;
a light-emitting layer disposed on the array substrate; and
the thin film encapsulation layer of claim 1 disposed on the array substrate and completely covering the light-emitting layer.
